(19) United States
(12) Patent Application Publication
(10) Pub. No.: US 2006/0062917 A1
(43) Pub. Date: Mar. 23, 2006

(54) Vapor deposition of hafnium silicate materials with tris(dimethylamino)silane

(76) Inventors: Shankar Muthukrishnan, San Jose, CA (US); Tejal Goyani, Sunnyvale, CA (US); Rahul Sharangpani, Fremont, CA (US); Shreyas S. Kher, Campbell, CA (US); Pravin K. Narwankar, Sunnyvale, CA (US); Khaled Z. Ahmed, Anaheim, CA (US); Yi Ma, Santa Clara, CA (US)

Correspondence Address: PATTERSON & SHERIDAN, LLP, 3040 POST OAK BOULEVARD, SUITE 1500, HOUSTON, TX, 77056, US

(21) Appl. No.: 11/223,896

(22) Filed: Sep. 9, 2005

Related U.S. Application Data
(63) Continuation-in-part of application No. 11/167,070, filed on Jun. 24, 2005.
Application No. 11/167,070 is a continuation-in-part of application No. 10/851,514, filed on May 21, 2004.

(51) Int. Cl. C23C 16/00

(52) U.S. Cl. 427/248.1

(57) ABSTRACT

In one embodiment, a method for forming a morphologically stable dielectric material is provided which includes exposing a substrate to a hafnium precursor, a silicon precursor and an oxidizing gas to form hafnium silicate material during a chemical vapor deposition (CVD) process and subsequently and optionally exposing the substrate to a post deposition anneal, a nitridation process and a thermal annealing process. In some examples, the hafnium and silicon precursors used during a metal-organic CVD (MOCVD) process are alkylamino compounds, such as tetrakis(diethylamino)hafnium (TDEAH) and tris(dimethylamino)silane (Tris-DMAS). In another embodiment, other metal precursors may be used to form a variety of metal silicates containing tantalum, titanium, aluminum, zirconium, lanthanum or combinations thereof.

### CROSS-REFERFENCE TO RELATED APPLICATION

This application is a continuation-in-part of U.S. Ser. No. 11/167,070 (APPM/009194.P1), entitled “Plasma Treatment of Hafnium-Containing Materials,” filed on Jun. 24, 2005, which is a continuation-in-part of U.S. Ser. No. 10/851,514 (APPM/009194), entitled “Stabilization of High-K Dielectric Materials,” filed on May 21, 2004, which are both hereby incorporated by reference in their entirety.

### BACKGROUND OF THE INVENTION

### Field of the Invention

Embodiments of the invention generally relate to methods for depositing materials on substrates, and more specifically, to methods for depositing and stabilizing dielectric materials while forming a dielectric stack.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 45 nm or smaller and aspect ratios of 10 or greater are being considered. Accordingly, conformal deposition of materials to form these devices is becoming increasingly important.

Conventional chemical vapor deposition (CVD) processes have been used to form a variety of materials required for device fabrication. High-k dielectric materials deposited by CVD processes for gate and capacitor applications include hafnium oxide, hafnium silicate, zirconium oxide, tantalum oxide among others. Dielectric materials, such as high-k dielectric materials, may experience morphological changes when exposed to high temperatures (>500° C.) during subsequent fabrication processes. For example, titanium nitride is often deposited on hafnium oxide or zirconium oxide by a CVD process at about 600° C. At such high temperature, the hafnium oxide or zirconium oxide may crystallize, loosing amorphousity and low leakage properties. Also, even if full crystallization of the dielectric material is avoided, exposure to high temperatures may form grain growth and/or phase separation of the dielectric material resulting in poor device performance due to high current leakage.

Therefore, there is a need for a process to form dielectric materials, especially high-k dielectric materials, which are morphologically stable to a high temperature exposure during a subsequent fabrication process.

### SUMMARY OF THE INVENTION

In one embodiment, a method for forming a dielectric material on a substrate is provided which includes exposing a substrate to a deposition gas containing an alkylamino hafnium precursor, an alkylamino silicon precursor and an oxidizing gas to deposit a hafnium silicate material thereon. Thereafter, the substrate may be exposed to a nitridation plasma process and/or a thermal annealing process to form a dielectric material thereon, such as a hafnium silicon oxynitride layer. The dielectric material may have a nitrogen concentration within a range from about 5 atomic percent (at %) to about 25 at %. In some examples, the substrate may be exposed to a pretreatment process or a preclean process prior to depositing the dielectric material. Other examples include conducting a post deposition annealing process prior to the nitridation process.

The method further provides that the alkylamino hafnium precursor used during the deposition process may be tetrakis(diethylamino)hafnium (TDEAH), tetrakis(dimethylamino)hafnium (TDMAH) or tetrakis(ethylmethylamino)hafnium (TEMAH), while the alkylamino silane may be tris(dimethylamino)silane (Tris-DMAS) or tetrakis(dimethylamino)silane (DMAS). In one example, TDEAH and Tris-DMAS are co-flowed into the process chamber together from independent precursor sources. In another example, TDEAH and Tris-DMAS are premixed as a precursor mixture and administered into the process chamber from a single precursor source. The oxidizing gas may contain oxygen, ozone or water. In a preferred example, a hafnium silicate material is formed from TDEAH, Tris-DMAS and oxygen during a thermal CVD process.

In another embodiment, a deposition process may be conducted to form a variety of metal silicates formed by substituting the hafnium precursor with an alternative metal precursor, such as a zirconium precursor, an aluminum precursor, a tantalum precursor, a titanium precursor, a lanthanum precursor or combinations thereof. Therefore, metal silicates containing tantalum, titanium, aluminum, zirconium or lanthanum may be formed by process described herein. In another aspect, the silicon precursor may be substituted with an aluminum precursor in order to form a variety of metal aluminates, such as hafnium aluminate or zirconium aluminate.

In an alternative embodiment, a method for forming a dielectric layer on a substrate is provided which includes positioning a substrate within a process chamber, flowing a hydrogen source gas and an oxygen source gas into a water vapor generator (WVG) system to form an oxidizing gas containing water vapor and exposing the substrate to a deposition gas containing a metal precursor, a silicon precursor and the oxidizing gas to deposit a metal silicate material thereon. In some examples, the composition of the water vapor is varied by controlling the delivery of the oxygen source gas and the hydrogen source gas into the WVG system. In one aspect, the flow rates of the oxygen source gas and the hydrogen source gas are adjusted to provide a predetermined water vapor composition. In another aspect, the concentrations of oxygen within the oxygen source gas and hydrogen within the hydrogen source gas are selected to provide a predetermined water vapor composition. The process further provides exposing the substrate to a nitridation plasma process and/or a thermal annealing process. In one example, a hafnium silicate material may be formed by using Tris-DMAS as a silicon precursor and TDEAH as a hafnium precursor.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of the invention and are therefore not to be considered limiting of its scope, for the invention may admit to other equally effective embodiments.

FIG. 1 illustrates a process sequence for forming a dielectric material according to one embodiment described herein; and

FIGS. 2A-2C depict a substrate during various stages of a process sequence according to one embodiment described herein.

### DETAILED DESCRIPTION OF THE PREFERRED EMBODIMENT

Embodiments of the invention provide methods for preparing dielectric materials used in a variety of applications, especially for high-k dielectric materials used in transistor and capacitor fabrication. A chemical vapor deposition (CVD) process may be used to control elemental composition of the formed dielectric compounds. In one embodiment, a dielectric material or a dielectric stack is prepared by depositing a dielectric layer containing a hafnium silicate material on a substrate during a metal-organic CVD (MOCVD) process, exposing the substrate to a nitridation process (e.g., nitrogen plasma) to form a hafnium silicon oxynitride material from the hafnium silicate and subsequently exposing the substrate to a thermal annealing process. Examples of the CVD process may include utilizing metal-organic hafnium precursors and silicon precursors, such as alkylamino compounds. Hafnium precursors may include tetrakis(dialkylamino)hafnium compounds, such as tetrakis(diethylamino)hafnium ((Et₂N)₄Hf or TDEAH), tetrakis(dimethylamino)hafnium ((Me₂N)₄Hf or TDMAH) and tetrakis(ethylmethylamino)hafnium ((EtMeN)₄Hf or TEMAH). Silicon precursors may include tris(dialkylamino)silanes and tetrakis(dialkylamino)silanes, such as tris(dimethylamino)silane ((Me₂N)₃SiH or Tris-DMAS) or tetrakis(dimethylamino)silane ((Me₂N)₄Si or DMAS). In some examples of the CVD process, oxidizing gas contains water vapor formed by flowing a hydrogen source gas and an oxygen source gas into a WVG system.

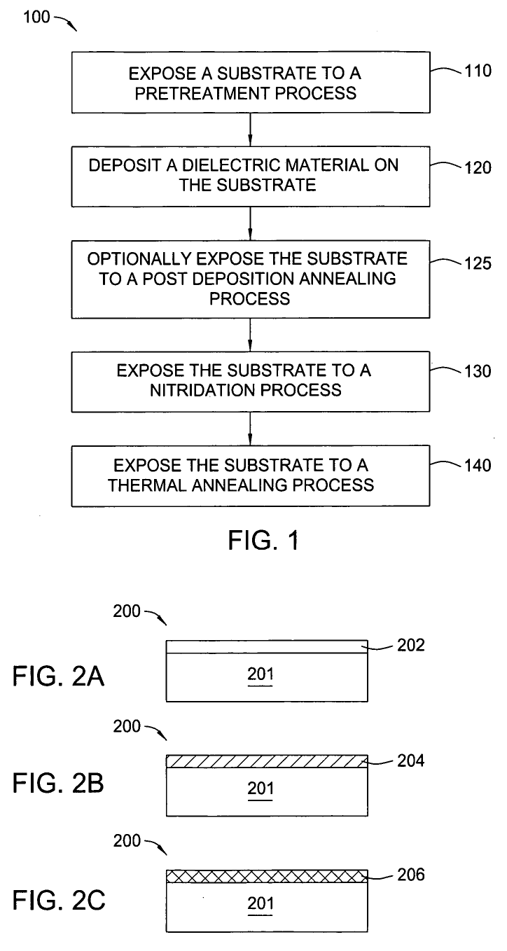

FIG. 1 illustrates an exemplary process 100 for forming a dielectric material, such as a metal silicon oxynitride material (e.g., HfSiₓO_{y}N_{z}). FIGS. 2A-2C depicts substrate 200 during different fabrication stages by process 100. Process 100 may form a dielectric material used within a semiconductor device, such as a transistor or a capacitor. Substrate 200 may be exposed to a pretreatment process (step 110). Thereafter, metal silicate material 202 is formed on substrate surface 201 by a CVD process described herein (step 120). In an optional step, substrate 200 may be exposed to a post deposition annealing process (step 125). Subsequently, substrate 200 is exposed to a nitridation process to form oxynitride material 204 (step 130) and then to a thermal annealing process (step 140) to form dielectric material 206 from oxynitride material 204.

Substrate 200 may be exposed to a treatment gas during a pretreatment process (step 110) to form functional groups terminated on substrate surface 201 prior to depositing metal silicate material 202. The functional groups provide a base for an incoming chemical precursor to attach or bind on substrate surface 201. The treatment gas may contain a chemical reagent, such as an oxidant, a reductant, an acid or a base. The treatment gas generally contains water vapor (e.g., deionized or from a WVG source), oxygen (O₂), ozone (O₃), hydrogen peroxide (H₂O₂), alcohols, hydrogen (H₂), atomic-H, atomic-N, atomic-O, ammonia (NH₃), diborane (B₂H₆), silane (SiH₄), disilane (Si₂H₆), hydrogen fluoride (e.g., HF-last solution), hydrogen chloride (HCl), amines, plasmas thereof, derivatives thereof or combination thereof. Functional groups that may be formed on substrate surface 201 include hydrogen (H), hydroxyl (OH), alkoxy (OR, where R=Me, Et, Pr or Bu), haloxyl (OX, where X=F, Cl, Br or I), halide (F, Cl, Br or I), oxygen radicals and aminos (NR or NR₂, where R=H, Me, Et, Pr or Bu). The pretreatment process may expose substrate 200 to the reagent for a time period within a range from about 1 second to about 10 minutes, preferably, from about 30 seconds to about 5 minutes, and more preferably, from about 60 seconds to about 4 minutes. A pretreatment process may include exposing substrate 200 to an RCA solution (SC1/SC2), an HF-last solution, water vapor from WVG or ISSG systems, peroxide solutions, acidic solutions, basic solutions, plasmas thereof, derivatives thereof or combinations thereof. Useful pretreatment processes are further described in commonly assigned U.S. Pat. No. 6,858,547 and commonly assigned, co-pending U.S. Ser. No. 10/302,752, filed Nov. 21, 2002, entitled, “Surface Pre-Treatment for Enhancement of Nucleation of High Dielectric Constant Materials,” and published as US 20030232501, which are both incorporated herein by reference in their entirety for the purpose of describing pretreatment methods and compositions of pretreatment solutions.

In one example of a pretreatment process, a native oxide layer is removed prior to exposing substrate 200 to a wet-clean process to form a chemical oxide layer having a thickness of about 10 Å or less, such as within a range from about 5 Å to about 7 Å. Native oxides may be removed by a HF-last solution (e.g., 0.5 wt % HF in water). The wet-clean process may be performed in a TEMPEST™ wet-clean system, available from Applied Materials, Inc., located in Santa Clara, Calif. In another example, substrate 200 is exposed to water vapor for about 15 seconds prior to starting a CVD process. The water vapor may be derived from a WVG system as further described herein.

Metal silicate material 202 may be formed on substrate surface 201 by a vapor deposition process, such as a CVD process, a plasma-enhanced CVD (PE-CVD) process, a pulsed CVD process, an ALD process, a PE-ALD process, a PVD process, a thermal-enhanced deposition technique, a plasma-enhanced deposition technique or a combination thereof (step 120). The CVD processes may be a conventional CVD process that provides a deposition gas with a constant gas flow or a pulsed CVD process that provides a pulsed or intermittent flow of a deposition gas of multiple chemical precursors. In a preferred example, metal silicate material 202 may be formed from a metal-organic precursor during a metal-organic CVD (MOCVD) process that provides thermal or plasma techniques and a constant or pulsed deposition gas.

Many precursors are within the scope of embodiments of the invention for depositing metal silicate material 202 and other dielectric materials described herein. One important precursor characteristic is to have a favorable vapor pressure. Precursors at ambient temperature and pressure may be gas, liquid or solid. However, volatilized precursors are used within the CVD chamber. Organometallic compounds contain at least one metal atom and at least one organic-containing functional group, such as amides, alkyls, alkoxyls, alkylaminos or anilides. Precursors may include metal-organic, organometallic, inorganic or halide compounds.

Exemplary hafnium precursors useful for depositing hafnium-containing materials and metal silicate materials 202 may contain ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials as described herein include (Et₂N)₄Hf (TDEAH), (Me₂)₄Hf (TDMAH), (EtMeN)₄Hf (TEMAH), (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (^{t}PrC₅H₄)₂HfCl₂, (^{t}PrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. Preferably, hafnium precursors used during the deposition process herein include HfCl₄, TDEAH, TDMAH and TEMAH.

Exemplary silicon precursors useful for depositing silicon-containing materials and metal silicate material 202 include silanes, alkylaminosilanes, silanols or alkoxy silanes. Silicon precursors may include (Me₂N)₄Si(DMAS), (Me₂N)₃SiH(Tris-DMAS), (Me₂N)₂SiH₂, (Me₂N)SiH₃, (Et₂N)₄Si(DMAS), (Et₂N)₃SiH(Tris-DMAS), (MeEtN)₄Si, (MeEtN)₃SiH, Si(NCO)₄, MeSi(NCO)₃, SiH₄, Si₂H₆, SiCl₄, Si₂Cl₆, MeSiCl₃, HSiCl₃, Me₂SiCl₂, H₂SiCl₂, MeSi(OH)₃, Me₂Si(OH)₂, (MeO)₄Si, (EtO)₄Si or derivatives thereof. Other alkylaminosilane compounds useful as silicon precursors include (RR′N)₄₋ₙSiHₙ, where R or R′ are independently hydrogen, methyl, ethyl, propyl or butyl and n=0-3. Other alkoxy silanes may be described by the generic chemical formula (RO)₄₋ₙSiLₙ, where R=methyl, ethyl, propyl or butyl and L=H, OH, F, Cl, Br or I and mixtures thereof. Preferably, silicon precursors used during deposition processes herein include DMAS Tris-DMAS and SiH₄.

The oxidizing gas for forming metal silicate material 202 and other dielectric materials as described herein may contain oxygen (O₂), ozone (O₃), atomic-oxygen (O), water (H₂O), hydrogen peroxide (H₂O₂), nitrous oxide (N₂O), nitric oxide (NO), dinitrogen pentoxide (N₂O₅), nitrogen dioxide (NO₂), derivatives thereof or combinations thereof. In one example, the oxidizing gas is oxygen, ozone or a combination thereof. In another example, an oxidizing gas contains water vapor formed by flowing a hydrogen source gas and an oxygen source gas into a catalytic water vapor generator (WVG) system.

In a CVD configuration of process 100, substrate 200 may be heated to a temperature within a range from about 400° C. to about 1,000° C., preferably, from about 600° C. to about 850° C., and more preferably, from about 550° C. to about 750° C., for example, about 700° C. Thereafter, substrate 200 is exposed to a process gas containing nitrogen (N₂) at a flow rate within a range from about 1 standard liters per minute (slm) to about 20 slm, preferably, from about 2 slm to about 10 slm, and more preferably, from about 4 slm to about 6 slm. Chemical precursors are added into the process gas to form a deposition gas. The deposition gas contains oxygen (O₂) at a flow rate within a range from about 1 slm to about 20 slm, preferably, from about 2 slm to about 10 slm, and more preferably, from about 4 slm to about 6 slm. A hafnium precursor may be added to the deposition gas and exposed to substrate 200 at a dosing rate within a range from about 1 milligram per minute (mg/min) to about 1,000 mg/min, preferably, from about 2 mg/min to about 100 mg/min, and more preferably, from about 5 mg/min to about 50 mg/min, for example, about 25 mg/min. A silicon precursor may be added to the deposition gas and exposed to substrate 200 at a dosing rate within a range from about 1 milligram per minute (mg/min) to about 1,000 mg/min, preferably, from about 2 mg/min to about 200 mg/min, and more preferably, from about 5 mg/min to about 100 mg/min, for example, about 50 mg/min. A carrier gas may be co-flowed with the hafnium precursor or the silicon precursor at a flow rate within a range from about 1 slm to about 5 slm, preferably, from about 0.7 slm to about 3 slm, and more preferably, from about 0.5 slm to about 2 slm.

The CVD process may last for a time period within a range from about 5 seconds to about 5 minutes, preferably, from about 10 seconds to about 4 minutes, and more preferably, from about 15 seconds to about 2.5 minutes. Metal silicate material 202 is deposited until a predetermined thickness is formed during the CVD process. Metal silicate material 202 is generally deposited having a film thickness within a range from about 5 Å to about 300 Å, preferably, from about 10 Å to about 200 Å, and more preferably, from about 20 Å to about 100 Å. In some example, metal silicate material 202 has a thickness within a range from about 10 Å to about 60 Å, preferably, from about 30 Å to about 40 Å. In one example, metal silicate material 202 is deposited with a thickness of about 40 Å by continuing a CVD process for a time period within a range from about 40 seconds to about 90 seconds, preferably, from about 60 seconds to about 70 seconds.

In a preferred embodiment, process 100 is performed within a single wafer process chamber to a single substrate contained therein. However, process 100 may be scaled-up and conducted within a batch process chamber containing a plurality of substrates, such as 4 substrates, 25 substrates, 50 substrates, 100 substrates or more. Further description of batch process chambers for conducting vapor deposition processes that may be used during embodiments described herein are available from Applied Materials, Inc., located in Santa Clara, Calif., and are further disclosed in commonly assigned U.S. Pat. Nos. 6,352,593 and 6,321,680, in commonly assigned and co-pending U.S. Ser. No. 10/342,151, filed Jan. 13, 2003, entitled, “Method and Apparatus for Layer by Layer Deposition of Thin Films,” and published as US 20030134038, and in commonly assigned and co-pending U.S. Ser. No. 10/216,079, filed Aug. 9, 2002, entitled, “High Rate Deposition at Low Pressure in a Small Batch Reactor,” and published as US 20030049372, which are incorporated herein by reference in their entirety for the purpose of describing apparatuses used during deposition processes.

In an alternative embodiment, metal silicate material 202 may be deposited by an ALD process. ALD processes and apparatuses useful to form metal silicate material 202 and other dielectric materials are further described in commonly assigned U.S. Pat. No. 6,916,398, and in commonly assigned and co-pending U.S. patent application Ser. Nos. 11/127,767 and 11/127,753, both filed May 12, 2005, and both entitled, “Apparatuses and Methods for Atomic Layer Deposition of Hafnium-containing High-K Materials,” which are incorporated herein by reference in their entirety for the purpose of describing methods and apparatuses used during ALD processes. Another useful ALD chamber is further described in commonly assigned U.S. Pat. No. 6,916,398, which is incorporated herein by reference in its entirety for the purpose of describing methods and apparatuses used during ALD processes.

Metal silicate material 202 may be deposited on substrate surface 201 containing a variety of compositions that are homogenous, heterogeneous or graded and may be a single layer, a multiple layered stack or a laminate. Metal silicate material 202 is a dielectric material that may contain hafnium, silicon and oxygen. In one example, metal silicate material 202 further contains nitrogen derived from decomposing the metal precursor and/or silicon precursor that contains nitrogen (e.g., alkylamino). In another example, metal silicate material 202 further contains nitrogen derived from a nitrogen precursor added into the deposition gas containing a metal precursor, a silicon precursor and an oxidizing gas. Although metal silicate material 202 preferably contains hafnium, other metals may be used as a substitute for hafnium, in combination with hafnium, or in combination with additional metals.

In an alternative embodiment, metal silicate material 202 may contain tantalum, titanium, aluminum, zirconium, lanthanum or combinations thereof. The metals may form silicate or oxide layers within metal silicate material 202. For example, metal silicate material 202 may contain hafnium oxide (HfOₓ or HfO₂), hafnium silicate (HfSiₓO_{y} or HfSiO₄), hafnium silicon oxynitride (HfSiₓO_{y}N_{z}), zirconium oxide (ZrOₓ or ZrO₂), zirconium silicate (ZrSiₓO_{y} or ZrSiO₄), zirconium silicon oxynitride (ZrSiₓO_{y}N_{z}), tantalum oxide (TaOₓ or Ta₂O₅), tantalum silicate (TaSiₓO_{y}), tantalum silicon oxynitride (TaSiₓO_{y}N_{z}), aluminum oxide (AlOₓ or Al₂O₃), aluminum silicate (AlSiₓO_{y}), aluminum silicon oxynitride (AlSiₓO_{y}N_{z}), lanthanum oxide (LaOₓ or La₂O₃), lanthanum silicate (LaSiₓO_{y}), lanthanum silicon oxynitride (LaSiₓO_{y}N_{z}), titanium oxide (TiOₓ or TiO₂), titanium silicate (TiSiₓO_{y}), titanium silicon oxynitride (TiSiₓO_{y}N_{z}), silicon oxynitride (SiO_{y}N_{z}), derivatives thereof or combinations thereof. Laminate films that are useful dielectric materials for metal silicate material 202 include HfO₂/SiO₂, HfO₂/SiO₂/Al₂O₃/SiO₂, HfO₂/SiO₂/La₂O₃/SiO₂, HfO₂/SiO₂/La₂O₃/SiO₂/Al₂O₃/SiO₂, derivatives thereof or combinations thereof. Preferably, metal silicate material 202 contains hafnium oxide, hafnium silicate and/or hafnium silicon oxynitride.

Particular precursors, process temperature and other variables may be adjusted to form a predetermined composition of metal silicate material 202. In one example, a hafnium silicate material is formed during a CVD process having a silicon concentration within a range from about 20 at % to about 80 at %, preferably, from about 40 at % to about 60 at %. In one example, metal silicate material 202 contains hafnium silicate with a chemical formula HfSiO₄. In another example, metal silicate material 202 contains hafnium silicate with a chemical formula HfSiₓO_{y}, wherein x is equal to or less than 1, such as within a range from about 0.1 to about 1 and y is equal to or less than 4, such as within a range from about 1 to about 4.

In one embodiment, substrate 200 is optionally be transferred into an annealing chamber and exposed to a post deposition annealing (PDA) process (step 125). The CENTURA™ RADIANCE™ RTP chamber, available from Applied Materials, Inc., located in Santa Clara, Calif., is an annealing chamber that may be used during the PDA process. The annealing chamber may be on the same cluster tool as the deposition chamber and/or the nitridation chamber, such that substrate 200 may be annealed without being exposed to the ambient environment. Substrate 200 may be heated to a temperature within a range from about 600° C. to about 1,200° C., preferably, from about 600° C. to about 1,150° C., and more preferably, from about 600° C. to about 1,000° C. The PDA process may last for a time period within a range from about 1 second to about 10 minutes, preferably, from about 5 seconds to about 5 minutes, and more preferably, from about 1 minute to about 4 minutes. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains nitrogen and at least one oxygen-containing gas, such as oxygen. The chamber may have a pressure within a range from about 5 Torr to about 100 Torr, for example, about 10 Torr. In one example of a PDA process, substrate 200, containing metal silicate material 202, is heated to a temperature of about 600° C. for about 4 minutes within an oxygen atmosphere.

During step 130, substrate 200 is exposed to a nitridation process that physically incorporates nitrogen atoms into metal silicate material 202 to form oxynitride material 204, as depicted in FIG. 2B. The nitridation process also increases the density of the material. The nitridation process may include decoupled plasma nitridation (DPN), remote plasma nitridation, hot-wired induced atomic-N, and nitrogen incorporation during dielectric deposition (e.g., during CVD process). Oxynitride material 204 is usually nitrogen-rich at the surface. The nitrogen concentration of oxynitride material 204 may be within a range from about 5 at % to about 40 at %, preferably, from about 10 at % to about 30 at %, and more preferably, from about 15 at % to about 25 at %, for example, about 20 at %. Preferably, the nitridation process exposes substrate 200 and metal silicate material 202 to a nitrogen plasma during a DPN process.

In one embodiment of a nitridation process, substrate 200 is transferred into a DPN chamber, such as the CENTURA™ DPN chamber, available from Applied Materials, Inc., located in Santa Clara, Calif. In one aspect, the DPN chamber is on the same cluster tool as the CVD chamber used to deposit metal silicate material 202 or the annealing chamber used during the PDA process. Therefore, substrate 200 may be exposed to a nitridation process without being exposed to the ambient environment.

During a DPN process, metal silicate material 202 is bombarded with atomic-N formed from a gas mixture of a nitrogen source gas and a noble gas plasma, such as an argon plasma. In one example, the gas mixture of the nitrogen source and the noble gas source may be introduced into the plasma chamber as a mixture. In another example, the nitrogen source and the noble gas source may be co-flowed or independently flowed introduced into the plasma chamber. Nitrogen source gases that may be used to form a nitrogen plasma include nitrogen (N₂), ammonia (NH₃), hydrazine (N₂H₄), methyl hydrazine (MeN₂H₃), dimethyl hydrazine (Me₂N₂H₂), tert-butyl hydrazine (^{t}BuN₂H₃), alkylamines (e.g., R₃N, R₂NH or RNH₂, where R is methyl, ethyl, propyl or butyl), anilines (e.g., C₆H₅NH₂), azides (e.g., MeN₃ or Me₃SiN₃), derivatives thereof or combinations thereof. Gases that may be used during the plasma process include argon, helium, neon, xenon or combinations thereof. In one example, a nitridation plasma contains nitrogen and argon, while in another example, a nitridation plasma contains ammonia and argon. The nitridation plasma has a nitrogen concentration within a range from about 5 vol % to about 95 vol %, preferably, from about 15 vol % to about 70 vol %, and more preferably, from about 20 vol % to about 60 vol % with a remainder of noble gas. In one example, the nitridation plasma contains no noble gas. Generally, the nitrogen concentration within the nitridation plasma is about 50 vol % or less. In one example, the nitrogen concentration is about 50 vol % and the noble gas concentration is about 50 vol %. In another example, the nitrogen concentration is about 40 vol % and the noble gas concentration is about 60 vol %. In another example, the nitrogen concentration is about 25 vol % and the noble gas concentration is about 75 vol %.

During the nitridation process in step 130, the nitrogen source gas may have a flow rate within a range from about 10 standard cubic centimeters per minute (sccm) to about 5 slm, preferably, from about 50 sccm to about 500 sccm, and more preferably, from about 100 sccm to about 250 sccm. The noble gas may have a flow rate within a range from about 10 sccm to about 5 slm, preferably, from about 50 sccm to about 750 sccm, and more preferably, from about 100 sccm to about 500 sccm. A deposition gas containing the nitrogen source and the noble gas may have a combined flow rate within a range from about 10 sccm to about 5 slm, preferably, from about 100 sccm to about 750 sccm, and more preferably, from about 200 sccm to about 500 sccm. The DPN chamber is generally under a reduced atmosphere, such as less than 760 Torr, preferably at a pressure within a range from about 1 mTorr to about 1 Torr, preferably from about 5 mTorr to about 500 mTorr, and more preferably, from about 10 mTorr to about 80 mTorr. The nitridation process proceeds at a time period within a range from about 10 seconds to about 5 minutes, preferably, from about 30 seconds to about 4 minutes, and more preferably, from about 1 minute to about 3 minutes. Also, the nitridation process may be conducted at a plasma power setting within a range from about 500 watts to about 3,000 watts, preferably from about 700 watts to about 2,500 watts, and more preferably, from about 900 watts to about 1,800 watts. Generally, the plasma process is conducted with a duty cycle of about 50% to about 100% and a pulse frequency at about 10 kHz. In a preferred embodiment, the nitridation process is a DPN process and includes a plasma by co-flowing argon and nitrogen.

In another embodiment, the process chamber used to deposit metal silicate material 202 is also used during a nitridation process to form oxynitride material 204 without transferring substrate 200 between process chambers. For example, a remote-plasma source (RPS) containing a nitrogen source is exposed to metal silicate material 202 to form oxynitride material 204 directly within a process chamber configured with a RPS device. Radical nitrogen compounds may also be produced by heat or hot-wires and used during the nitridation processes. Other nitridation processes to form oxynitride material 204 are contemplated, such as annealing the substrate within a nitrogen-rich environment. In an alternative embodiment, a nitrogen precursor is included within a deposition gas during the CVD process while forming oxynitride material 204. For example, a nitrogen precursor, such as ammonia, may be co-flowed continuous or intermediate with a deposition gas containing a metal precursor (e.g., a hafnium precursor), a silicon precursor and an oxidizing gas during a CVD process to form metal silicate material 202.

As depicted in FIG. 2C, substrate 200 may be exposed to a thermal annealing process, such as a post nitridation anneal (PNA) process, to form dielectric material 206 from oxynitride material 204 (step 140). In one example, substrate 200 may be transferred into an annealing chamber, such as the CENTURA™ RADIANCE™ RTP chamber, available from Applied Materials, Inc., located in Santa Clara, Calif., and exposed to the thermal annealing process. The annealing chamber may be on the same cluster tool as the deposition chamber and/or the nitridation chamber, such that substrate 200 may be annealed without being exposed to the ambient environment. Substrate 200 may be heated to a temperature within a range from about 600° C. to about 1,200° C., preferably from, about 700° C. to about 1,150° C., and more preferably, from about 800° C. to about 1,000° C. The thermal annealing process may last for a time period within a range from about 1 second to about 120 seconds, preferably, from about 2 seconds to about 60 seconds, and more preferably, from about 5 seconds to about 30 seconds. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains a nitrogen source and at least one oxidizing gas. The annealing chamber may have a pressure within a range from about 5 Torr to about 100 Torr, for example, about 10 Torr. In one example, substrate 200 is heated to a temperature of about 1,050° C. for about 15 seconds within an oxygen atmosphere during a thermal annealing process. In another example, substrate 200 is heated to a temperature of about 1,100° C. for about 25 seconds within an atmosphere containing equivalent volumetric amounts of nitrogen and oxygen.

The thermal annealing or PNA process may be used to repair damage on substrate 200 caused by plasma bombardment and to reduce the fixed charge of dielectric material 206 (step 140). Dielectric material 206 remains amorphous and may have a nitrogen concentration within a range from about 5 at % to about 25 at %, preferably from about 10 at % to about 20 at %, for example, about 15 at %. In one example, dielectric material 206 contains hafnium silicon oxynitride with a chemical formula HfSiO₄N_{z}, wherein z is within a range from about 0.2 to about 2, preferably, from about 0.5 to about 1.2, and more preferably, from about 0.8 to about 1.0. In another example, dielectric material 206 contains hafnium silicon oxynitride with a chemical formula HfSiₓO_{y}N_{z}, wherein x is equal to or less than 1, such as within a range from about 0.1 to about 1, y is equal to or less than 4, such as within a range from about 1 to about 4 and z is within a range from about 0.2 to about 2, preferably, from about 0.5 to about 1.2, and more preferably from about 0.8 to about 1.0. In some of the examples, dielectric material 206 may have a film thickness within a range from about 5 Å to about 300 Å, preferably, from about 10 Å to about 200 Å, and more preferably, from about 20 Å to about 100 Å. In other examples, dielectric material 206 has a thickness within a range from about 10 Å to about 60 Å, preferably from about 30 Å to about 40 Å.

An equivalent oxide thickness (EOT) standard may be used to compare the performance of a high-K dielectric material within a MOS gate to the performance of a silicon oxide (SiO₂) based material within a MOS gate. An EOT value correlates to a thickness of the high-k dielectric material needed to obtain the same gate capacitance as a thickness of the silicon oxide material. Since (as the name implies) high-K dielectric materials have a higher dielectric constant (K) than does silicon dioxide which is about 3.9, then a correlation between thickness of a material and the K value of a material may be evaluated by the EOT value. In one example, dielectric material 206 with a K value of about 32 and a layer thickness of about 5 nm has an EOT value of about 0.6 nm. Therefore, a lower EOT value may be realized by increasing the K value of the dielectric material, densifying the dielectric material to decrease the thickness.

In an alternative embodiment to deposit a dielectric material, a nitrogen precursor may be used with a hafnium precursor, a silicon precursor and/or an oxygen precursor during a CVD process. Therefore, a nitrogen containing hafnium compound may include hafnium nitride, hafnium silicon nitride, hafnium oxynitride, hafnium silicon oxynitride or a derivative thereof. Exemplary nitrogen precursors may include ammonia (NH₃), nitrogen (N₂), hydrazines (e.g., N₂H₄ or MeN₂H₃), amines (e.g., Me₃N, Me₂NH or MeNH₂), anilines (e.g., C₆H₅NH₂), organic azides (e.g., MeN₃ or Me₃SiN₃), inorganic azides (e.g., NaN₃ or Cp₂CoN₃), radical nitrogen compounds (e.g., N₃, N₂, N, NH or NH₂), derivatives thereof or combinations thereof. Radical nitrogen compounds may be produced by heat, hot-wires or plasma.

In an alternative embodiment of process 100, a variety of metal silicates, metal oxides, metal oxynitrides or metal silicon oxynitrides may be formed during the deposition processes described herein (step 120). A deposition process for forming a hafnium-containing material may be altered by substituting the hafnium precursor and/or the silicon precursor with other metal precursors to form additional dielectric materials, such as hafnium aluminate, titanium silicate, titanium aluminate, titanium oxynitride, titanium silicon oxynitride, zirconium oxide, zirconium silicate, zirconium oxynitride, zirconium aluminate, tantalum oxide, tantalum silicate, tantalum oxynitride, titanium oxide, aluminum oxide, aluminum silicate, aluminum oxynitride, lanthanum oxide, lanthanum silicate, lanthanum oxynitride, lanthanum aluminate, derivatives thereof or combinations thereof. Alternative metal precursors used during vapor deposition processes described herein include ZrCl₄, Cp₂Zr, (Me₂N)₄Zr, (Et₂N)₄Zr, TaF₅, TaCl₅, (^{t}BuO)₅Ta, (Me₂N)₅Ta, (Et₂N)₅Ta, (Me₂N)₃Ta(N^{t}Bu), (Et₂N)₃Ta(N^{t}Bu), TiCl₄, Til₄, (ⁱPrO)₄Ti, (Me₂N)₄Ti, (Et₂N)₄Ti, AlCl₃, Me₃Al, Me₂AlH, (AMD)₃La, ((Me₃Si)(tBu)N)₃La, ((Me₃Si)₂N)₃La, (^{t}Bu₂N)₃La, (ⁱPr₂N)₃La, derivatives thereof or combinations thereof.

In another embodiment, hydrogen gas is applied as a carrier gas, purge and/or a reactant gas to reduce halogen contamination from the deposited materials. Precursors that contain halogen atoms (e.g., HfCl₄, ZrCl₄ and TaF₅) readily contaminate the deposited dielectric materials. Hydrogen is a reductant and will produce hydrogen halides (e.g., HCl or HF) as a volatile and removable by-product. Therefore, hydrogen may be used as a carrier gas or reactant gas when combined with a precursor compound (e.g., hafnium precursors) and may include another carrier gas (e.g., Ar or N₂). In one example, a water/hydrogen mixture, at a temperature within a range from about 100° C. to about 500° C., is used to reduce the halogen concentration and increase the oxygen concentration of the deposited material. In one example, a water/hydrogen mixture may be derived by feeding an excess of hydrogen source gas into a WVG system to form a hydrogen enriched water vapor.

In an alternative example, the oxidizing gas may be produced from a water vapor generator (WVG) system in fluid communication with the process chamber. The WVG system generates ultra-high purity water vapor by means of a catalytic reaction of an oxygen source gas (e.g., O₂) and a hydrogen source gas (e.g., H₂) at a low temperature (e.g., <500° C.). The hydrogen and oxygen source gases each flow into the WVG system at a flow rate within the range from about 5 sccm to about 200 sccm, preferably, from about 10 sccm to about 100 sccm. Generally, the flow rates of the oxygen and hydrogen source gases are independently adjusted to have a presence of oxygen or an oxygen source gas and an absence of the hydrogen or hydrogen source gas within the outflow of the oxidizing gas.

An oxygen source gas useful to generate an oxidizing gas containing water vapor may include oxygen (O₂), atomic oxygen (O), ozone (O₃), nitrous oxide (N₂O), nitric oxide (NO), nitrogen dioxide (NO₂), dinitrogen pentoxide (N₂O₅), hydrogen peroxide (H₂O₂), derivatives thereof or combinations thereof. A hydrogen source gas useful to generate an oxidizing gas containing water vapor may include hydrogen (H₂), atomic hydrogen (H), forming gas (N₂/H₂), ammonia (NH₃), hydrocarbons (e.g., CH₄), alcohols (e.g., CH₃OH), derivatives thereof or combinations thereof. A carrier gas may be co-flowed with either the oxygen source gas or the hydrogen source gas and may include N₂, He, Ar or combinations thereof. Preferably, the oxygen source gas is oxygen or nitrous oxide and the hydrogen source gas is hydrogen or a forming gas, such as 5 vol % of hydrogen in nitrogen.

A hydrogen source gas and an oxygen source gas may be diluted with a carrier gas to provide sensitive control of the water vapor within the oxidizing gas during deposition processes. In one embodiment, a slower water vapor flow rate (about <10 sccm water vapor) may be desirable to complete the chemical reaction during a CVD process to form a hafnium-containing material or other dielectric materials. A slower water vapor flow rate dilutes the water vapor concentration within the oxidizing gas. The diluted water vapor is at a concentration to oxidize adsorbed precursors on the substrate surface. Therefore, a slower water vapor flow rate minimizes the purge time after the water vapor exposure to increase the fabrication throughput. Also, the slower water vapor flow rate reduces formation of particulate contaminants by avoiding undesired co-reactions. A mass flow controller (MFC) may be used to control a hydrogen source gas with a flow rate of about 0.5 sccm while producing a stream of water vapor with a flow rate of about 0.5 sccm. However, most MFC systems are unable to provide a consistent flow rate at such a slow rate. Therefore, a diluted hydrogen source gas (e.g., forming gas) may be used in a WVG system to achieve a slower water vapor flow rate. In one example, a hydrogen source gas with a flow rate of about 10 sccm and containing 5% hydrogen forming gas delivers water vapor from a WVG system with a flow rate of about 0.5 sccm. In an alternative embodiment, a faster water vapor flow rate (about >10 sccm water vapor) may be desirable to complete the chemical reaction during A CVD process while forming a hafnium-containing material or other dielectric materials. For example, about 100 sccm of hydrogen gas delivers about 100 sccm of water vapor.

The forming gas may be selected with a hydrogen concentration within a range from about 1% to about 95% by volume in a carrier gas, such as argon or nitrogen. In one aspect, a hydrogen concentration of a forming gas is within a range from about 1% to about 30% by volume in a carrier gas, preferably from about 2% to about 20%, and more preferably, from about 3% to about 10%, for example, a forming gas may contain about 5% hydrogen and about 95% nitrogen. In another aspect, a hydrogen concentration of a forming gas is within a range from about 30% to about 95% by volume in a carrier gas, preferably from about 40% to about 90%, and more preferably from about 50% to about 85%, for example, a forming gas may contain about 80% hydrogen and about 20% nitrogen.

In one example, a WVG system receives a hydrogen source gas containing 5% hydrogen (95% nitrogen) with a flow rate of about 10 sccm and an oxygen source gas (e.g., O₂) with a flow rate of about 10 sccm to form an oxidizing gas containing water vapor with a flow rate of about 0.5 sccm and oxygen with a flow rate of about 9.8 sccm. In another example, a WVG system receives a hydrogen source gas containing 5% hydrogen forming gas with a flow rate of about 20 sccm and an oxygen source gas with a flow rate of about 10 sccm to form an oxidizing gas containing water vapor with a flow rate of about 1 sccm and oxygen with a flow rate of about 9 sccm. In another example, a WVG system receives a hydrogen source gas containing hydrogen gas with a flow rate of about 20 sccm and an oxygen source gas with a flow rate of about 10 sccm to form an oxidizing gas containing water vapor at a rate of about 10 sccm and oxygen at a rate of about 9.8 sccm. In other examples, nitrous oxide, as an oxygen source gas, is used with a hydrogen source gas to form a water vapor during deposition processes. Generally, 2 molar equivalents of nitrous oxide are substituted for each molar equivalent of oxygen gas.

A WVG system may contain a catalyst, such as catalyst-lined reactor or a catalyst cartridge, in which the oxidizing gas containing water vapor is generated by a catalytic chemical reaction between a source of hydrogen and a source of oxygen. A WVG system is unlike pyrogenic generators that produce water vapor as a result of an ignition reaction, usually at temperatures over 1,000° C. A WVG system containing a catalyst usually produces water vapor at a low temperature within a range from about 100° C. to about 500° C., preferably at about 350° C. or less. The catalyst contained within a catalyst reactor may include a metal or alloy, such as palladium, platinum, nickel, iron, chromium, ruthenium, rhodium, alloys thereof or combinations thereof. The ultra-high purity water is ideal for the CVD processes of the present invention. In one embodiment, to prevent unreacted hydrogen from flowing downstream, an oxygen source gas is allowed to flow through the WVG system for about 5 seconds. Next, the hydrogen source gas is allowed to enter the reactor for about 5 seconds. The catalytic reaction between the oxygen and hydrogen source gases (e.g., H₂ and O₂) generates a water vapor. Regulating the flow of the oxygen and hydrogen source gases allows precise control of oxygen and hydrogen concentrations within the formed oxidizing gas containing water vapor. The water vapor may contain remnants of the hydrogen source gas, the oxygen source gas or combinations thereof. Suitable WVG systems are commercially available, such as the Water Vapor Generator (WVG) system by Fujikin of America, Inc., located in Santa Clara, Calif. or the Catalyst Steam Generator System (CSGS) by Ultra Clean Technology, located in Menlo Park, Calif.

A “substrate surface,” as used herein, refers to any substrate or material surface formed on a substrate upon which film processing is performed. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein, may be used to form dielectric materials and hafnium-containing materials on many substrates and surfaces. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

### EXAMPLES

The hypothetic examples 1-4 may be conducted on a CENTURA® platform containing a TEMPEST™ wet-clean system, a CVD chamber, a CENTURA® DPN (decoupled plasma nitridation) chamber and a CENTURA® RADIANCE® RTP (thermal annealing) chamber, all available from Applied Materials, Inc., located in Santa Clara, Calif. Experiments may be conducted on 300 mm diameter substrates and substrate surfaces that were exposed to a HF-last solution to remove native oxides and subsequently placed into the wet-clean system to form a chemical oxide layer having a thickness of about 5 Å. The WVG system, having a metal catalyst, is available from Fujikin of America, Inc., located in Santa Clara, Calif. The WVG system may produce an oxidizing gas containing water vapor from a hydrogen source gas (5 vol % H₂ in N₂) and an oxygen source gas (O₂).

### Example 1

A substrate containing a chemical oxide surface was placed into the CVD chamber. A hafnium silicate layer was formed during a CVD process by exposing the substrate to a deposition gas containing TDEAH, Tris-DMAS and oxygen. The CVD process was continued until the hafnium silicate layer was about 40 Å thick. The substrate was transferred into the DPN chamber and exposed to a nitridation plasma process to densify and incorporate nitrogen atoms within the hafnium silicate material. The nitridation process contained an argon flow rate of about 160 sccm and a nitrogen flow rate of about 40 sccm for about 180 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 10 Torr.

### Example 2

A substrate containing a chemical oxide surface was placed into the CVD chamber. A hafnium silicate layer was formed during a CVD process by exposing the substrate to a deposition gas containing TDEAH, DMAS and oxygen. The CVD process was continued until the hafnium silicate layer was about 40 Å thick. The substrate was transferred into the DPN chamber and exposed to a nitridation plasma process to density and incorporate nitrogen atoms within the hafnium silicate material. The nitridation process contained an argon flow rate of about 160 sccm and an ammonia flow rate of about 40 sccm for about 180 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 10 Torr.

### Example 3

A substrate containing a chemical oxide surface was placed into the CVD chamber. A hafnium silicate layer was formed during a CVD process by exposing the substrate to a deposition gas containing TEMAH, Tris-DMAS and water vapor from a WVG. The CVD process was continued until the hafnium silicate layer was about 40 Å thick. The substrate was transferred into the DPN chamber and exposed to a nitridation plasma process to densify and incorporate nitrogen atoms within the hafnium silicate material. The nitridation process contained an argon flow rate of about 160 sccm and a nitrogen flow rate of about 40 sccm for about 180 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 10 Torr.

### Example 4

A substrate containing a chemical oxide surface was placed into the CVD chamber. A hafnium silicate layer was formed during a CVD process by exposing the substrate to a deposition gas containing TDEAH, DMAS and water vapor from a WVG. The CVD process was continued until the hafnium silicate layer was about 40 Å thick. The substrate was transferred into the DPN chamber and exposed to a nitridation plasma process to densify and incorporate nitrogen atoms within the hafnium silicate material. The nitridation process contained an argon flow rate of about 160 sccm and an ammonia flow rate of about 40 sccm for about 180 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 10 Torr.

While the foregoing is directed to embodiments of the invention, other and further embodiments of the invention may be devised without departing from the basic scope thereof, and the scope thereof is determined by the claims that follow.

1. A method for forming a dielectric layer on a substrate, comprising:
exposing a substrate to a deposition gas containing an alkylamino hafnium precursor, an alkylamino silicon precursor and an oxidizing gas to deposit a hafnium silicate material thereon;
exposing the substrate to a nitridation plasma process to form a hafnium silicon oxynitride layer thereon; and
exposing the substrate to a thermal annealing process to form a dielectric material.

2. The method of claim 1, wherein the alkylamino hafnium precursor has a chemical formula (RR′N)₄Hf, where R and R′ are each independently selected from a group consisting of methyl, ethyl, propyl, butyl, pentyl, derivatives thereof and combinations thereof.

3. The method of claim 2, wherein the alkylamino hafnium precursor is selected from a group consisting of tetrakis(diethylamino)hafnium, tetrakis(dimethylamino)hafnium, tetrakis(ethylmethylamino)hafnium and derivatives thereof.

4. The method of claim 1, wherein the alkylamino silicon precursor has a chemical formula (RR′N)ₙSiH₄₋ₙ, where R and R′ are each independently selected from a group consisting of methyl, ethyl, propyl, butyl, pentyl, derivatives thereof and combinations thereof.

5. The method of claim 4, wherein the alkylamino silicon precursor is selected from a group consisting of a bis(dialkylamino)silane, a tris(dialkylamino)silane, a tetrakis(dialkylamino)silane and derivatives thereof.

6. The method of claim 5, wherein the alkylamino silicon precursor is selected from a group consisting of, such as tris(dimethylamino)silane, tetrakis(dimethylamino)silane, tris(diethylamino)silane, tetrakis(diethylamino)silane, tris(ethylmethylamino)silane, tetrakis(ethylmethylamino)silane and derivatives thereof.

7. The method of claim 6, wherein the deposition gas contains tetrakis(diethylamino)hafnium, tris(dimethylamino)silane or combinations thereof.

8. The method of claim 1, wherein the nitridation plasma process occurs for a time period within a range from about 1 minute to about 3 minutes and at a power output within a range from about 900 watts to about 1,800 watts.

9. The method of claim 8, wherein the nitridation plasma process comprises a deposition gas containing a nitrogen concentration of about 50 vol % or less.

10. The method of claim 9, wherein the dielectric material has a nitrogen concentration within a range from about 10 at % to about 30 at %.

11. The method of claim 8, wherein the thermal annealing process occurs for a time period within a range from about 5 seconds to about 30 seconds and at a temperature within a range from about 800° C. to about 1,100° C.

12. The method of claim 11, wherein the thermal annealing process further comprises oxygen.

13. The method of claim 12, wherein the dielectric material has a thickness within a range from about 5 Å to about 100 Å.

14. The method of claim 8, wherein the substrate is exposed to a post deposition annealing process after depositing the hafnium silicate material and prior to the nitridation plasma process.

15. The method of claim 8, wherein the substrate is exposed to a wet clean process prior to depositing the hafnium silicate material.

16. The method of claim 15, wherein the wet clean process forms an oxide layer with a thickness of about 10 Å or less.

17. The method of claim 8, wherein the oxidizing gas comprises water vapor and is formed by flowing a hydrogen source gas and an oxygen source gas into a water vapor generator.

18. A method for forming a dielectric layer on a substrate, comprising:
positioning a substrate within a process chamber;
flowing a hydrogen source gas and an oxygen source gas into a water vapor generator to form an oxidizing gas comprising water vapor;
exposing the substrate to a deposition gas containing a hafnium precursor, a silicon precursor and the oxidizing gas to deposit a hafnium silicate material thereon;
exposing the substrate to a nitridation plasma process to form a hafnium silicon oxynitride layer thereon; and
exposing the substrate to a thermal annealing process to form a dielectric material.

19. The method of claim 18, wherein the deposition gas contains an alkylamino hafnium precursor, an alkylamino silicon precursor.

20. The method of claim 19, wherein the alkylamino hafnium precursor has a chemical formula (RR′N)₄Hf, where R and R′ are each independently selected from a group consisting of methyl, ethyl, propyl, butyl, pentyl, derivatives thereof and combinations thereof.

21. The method of claim 20, wherein the alkylamino hafnium precursor is selected from a group consisting of tetrakis(diethylamino)hafnium, tetrakis(dimethylamino)hafnium, tetrakis(ethylmethylamino)hafnium and derivatives thereof.

22. The method of claim 19, wherein the alkylamino silicon precursor has a chemical formula (RR′N)ₙSiH₄₋ₙ, where R and R′ are each independently selected from a group consisting of methyl, ethyl, propyl, butyl, pentyl, derivatives thereof and combinations thereof.

23. The method of claim 22, wherein the alkylamino silicon precursor is selected from a group consisting of a tris(dialkylamino)silane, a tetrakis(dialkylamino)silane and derivatives thereof.

24. The method of claim 23, wherein the alkylamino silicon precursor is selected from a group consisting of, such as tris(dimethylamino)silane, tetrakis(dimethylamino)silane, tris(diethylamino)silane, tetrakis(diethylamino)silane, tris(ethylmethylamino)silane, tetrakis(ethylmethylamino)silane and derivatives thereof.

25. The method of claim 24, wherein the deposition gas contains tetrakis(diethylamino)hafnium, tris(dimethylamino)silane or combinations thereof.

26. A method for forming a dielectric layer on a substrate, comprising:
exposing a substrate to a deposition gas containing an alkylamino hafnium precursor, tris(dimethylamino)silane and an oxidizing gas to deposit a hafnium silicate material thereon;
exposing the substrate to a nitridation plasma process to form a hafnium silicon oxynitride layer thereon; and
exposing the substrate to a thermal annealing process to form a dielectric material.

27. The method of claim 26, wherein the alkylamino hafnium precursor is selected from a group consisting of tetrakis(diethylamino)hafnium, tetrakis(dimethylamino)hafnium, tetrakis(ethylmethylamino)hafnium and derivatives thereof.

28. The method of claim 26, wherein the oxidizing gas comprises water vapor and is formed by flowing a hydrogen source gas and an oxygen source gas into a water vapor generator.

29. A method for forming a dielectric layer on a substrate, comprising:
exposing a substrate to a deposition gas containing at least one metal precursor, tris(dimethylamino)silane and an oxidizing gas to deposit a metal silicate material thereon;
exposing the substrate to a nitridation plasma process to form a metal silicon oxynitride layer thereon; and
exposing the substrate to a thermal annealing process to form a dielectric material.

30. The method of claim 29, wherein the oxidizing gas comprises water vapor and is formed by flowing a hydrogen source gas and an oxygen source gas into a water vapor generator.

31. The method of claim 30, wherein the metal silicate material comprises at least one element selected from the group consisting of hafnium, tantalum, titanium, aluminum, zirconium, lanthanum and combinations thereof.

32. The method of claim 31, wherein the at least one metal precursor is selected from the group consisting of a hafnium precursor, a zirconium precursor, an aluminum precursor, a tantalum precursor, a titanium precursor, a lanthanum precursor and combinations thereof.

33. A method for forming a dielectric layer on a substrate, comprising:
positioning a substrate within a process chamber;
flowing a hydrogen source gas and an oxygen source gas into a water vapor generator to form an oxidizing gas comprising water vapor;
exposing the substrate to a deposition gas containing a metal precursor, a silicon precursor and the oxidizing gas to deposit a metal silicate material thereon;
exposing the substrate to a nitridation plasma process; and
exposing the substrate to a thermal annealing process.

34. A method for forming a dielectric layer on a substrate, comprising:
exposing a substrate to a deposition gas containing a tetrakis(alkylamino) hafnium precursor, an alkylamino silicon precursor and oxygen gas to deposit a hafnium silicate material thereon; and
exposing the substrate to a nitridation plasma process and subsequently to a thermal annealing process to form a dielectric material.
